(19) United States
(12) Patent Application Publication
(10) Pub. No.: US 2009/0242960 A1
(43) Pub. Date: Oct. 1, 2009

(54) SEMICONDUCTOR MEMORY DEVICE AND MANUFACTURING METHOD THEREOF

(76) Inventor: Makoto SAKUMA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/407,131

(22) Filed: Mar. 19, 2009

(30) Foreign Application Priority Data
Mar. 27, 2008 (JP) 2008-083421

(51) Int. Cl. H01L 29/788; H01L 21/8239

(52) U.S. Cl. 257/321; 438/238; 257/380; 257/369; 438/257; 257/E29.3; 257/E21.645

(57) ABSTRACT

A semiconductor memory device includes a semiconductor substrate, a memory cell provided on the semiconductor substrate and having a stacked gate structure formed by sequentially stacking a tunnel insulation film, a charge storage layer, a block insulation film, and a control gate electrode, a first transistor having a first gate electrode provided on the semiconductor substrate via a gate insulation film, and a resistor element provided on the semiconductor substrate and formed of polysilicon. The control gate electrode is entirely formed of a silicide layer. An upper portion of the first gate electrode partially includes a silicide layer.

### CROSS-REFERENCE TO RELATED APPLICATIONS

This application is based upon and claims the benefit of priority from prior Japanese Patent Application No. 2008-083421, filed Mar. 27, 2008, the entire contents of which are incorporated herein by reference.

### BACKGROUND OF THE INVENTION

1. Field of the Invention

The present invention relates to a semiconductor memory device and a manufacturing method thereof, such as a semiconductor memory device comprising a flash memory and a manufacturing method thereof.

2. Description of the Related Art

A flash memory, which is a kind of electrically erasable programmable read-only memory (EEPROM) and configured to electrically write and erase data, is known as a non-volatile semiconductor memory. Further, a metal oxide nitride oxide semiconductor (MONOS) flash memory cell is known as a kind of flash memory. A MONOS cell uses a cell transistor having the structure formed of a metal, an oxide film, a nitride film, an oxide film, and a semiconductor region, which structure is suitable for miniaturization. A cell transistor which uses silicon nitride as a charge storage layer, for example, is capable of low-voltage writing and low-voltage erasure operations, compared to a floating gate cell transistor.

A fully silicided (FUSI) structure obtained by fully siliciding polysilicon used for gate electrodes has been used in cell transistors. By fully siliciding gate electrodes, properties of cell transistor can be improved. In the conventional manufacturing method, however, by fully siliciding gate electrodes of cell transistors, a gate electrode of a metal oxide semiconductor (MOS) transistor and a resistor element using polysilicon are also fully silicided, which causes problems which will be described below.

That is, in the MOS transistor, variation in threshold voltage increases, which inevitably causes increase in variation in operation properties. In the resistor element, the resistance value decreases, which inevitably causes increase in element area such that a desired resistance value is obtained.

When the gate electrode of the MOS transistor is not silicided at all, on the other hand, the resistance value of the gate electrode increases, which causes the problem of voltage drop, and thereby the operation rate inevitably decreases.

As a related technique of this kind, the technique of fabricating a gate electrode of a field-effect transistor by discriminating between a fully silicided gate and a partially silicided gate has been disclosed (Jpn. Pat. Appln. KOKAI Publication 2005-228868).

### BRIEF SUMMARY OF THE INVENTION

According to an aspect of the present invention, there is provided a semiconductor memory device comprising: a semiconductor substrate; a memory cell provided on the semiconductor substrate and having a stacked gate structure formed by sequentially stacking a tunnel insulation film, a charge storage layer, a block insulation film, and a control gate electrode; a first transistor having a first gate electrode provided on the semiconductor substrate via a gate insulation film; and a resistor element provided on the semiconductor substrate and formed of polysilicon. The control gate electrode is entirely formed of a silicide layer. An upper portion of the first gate electrode partially includes a silicide layer.

According to an aspect of the present invention, there is provided a manufacturing method of a semiconductor memory device, the method comprising: forming a memory cell having a stacked gate structure formed by sequentially stacking a tunnel insulation film, a charge storage layer, a block insulation film, and a control gate electrode formed of polysilicon on a first region of a semiconductor substrate; forming a transistor having a gate electrode provided on a second region of the semiconductor substrate via a gate insulation film, the gate electrode being formed of polysilicon; forming a resistor element formed of polysilicon on a third region of the semiconductor substrate; depositing an insulation layer on the first region and the second region of the semiconductor substrate to fill in spaces between elements; forming a barrier film on an upper surface and side surfaces of the resistor element; etching back an insulation layer of the second region to a first depth to expose a part of the gate electrode; etching back an insulation layer of the first region to a second depth greater than the first depth to expose a part of the control gate electrode; forming a metal film on the exposed parts of the control gate electrode and the gate electrode; and performing heat treatment to cause reaction between the metal film and the polysilicon.

According to an aspect of the present invention, there is provided a manufacturing method of a semiconductor memory device, the method comprising: forming a memory cell having a stacked gate structure formed by sequentially stacking a tunnel insulation film, a charge storage layer, a block insulation film, and a control gate electrode formed of polysilicon on a first region of a semiconductor substrate; forming a transistor having a gate electrode provided on a second region of the semiconductor substrate via a gate insulation film, the gate electrode being formed of polysilicon; forming a resistor element formed of polysilicon on a third region of the semiconductor substrate; depositing an insulation layer on the first region and the second region of the semiconductor substrate to fill in spaces between elements; forming a barrier film on an upper surface and side surfaces of the resistor element; etching back the insulation layer to a first depth to expose an upper portion of the control gate electrode and an upper portion of the gate electrode; forming a first metal film in the exposed portions of the control gate electrode and the gate electrode; performing a first heat treatment to cause reaction between the first metal film and the polysilicon; forming a resist to cover the exposed portion of the gate electrode; forming a second metal film on the exposed portion of the control gate electrode; and performing a second heat treatment to cause reaction between the second metal film and the polysilicon.

### BRIEF DESCRIPTION OF THE SEVERAL VIEWS OF THE DRAWING

FIG. 1 is a circuit diagram showing a configuration of a block included in a NAND flash memory according to a first embodiment of the present invention;

FIG. 2 is a cross-sectional view showing a configuration of a memory cell transistor MT;

FIG. 3 is a cross-sectional view showing a configuration of a selective transistor ST;

FIG. 4 is a cross-sectional view showing a configuration of a resistor element 24;

FIG. 5 is a cross-sectional view showing a manufacturing step of the semiconductor memory device according to the first embodiment;

FIG. 6 is a cross-sectional view showing a manufacturing step of the semiconductor memory device following FIG. 5;

FIG. 7 is a cross-sectional view showing a manufacturing step of the semiconductor memory device following FIG. 6;

FIG. 8 is a cross-sectional view showing a manufacturing step of the semiconductor memory device following FIG. 7;

FIG. 9 is a cross-sectional view showing a manufacturing step of the semiconductor memory device following FIG. 8;

FIG. 10 is a cross-sectional view showing a manufacturing step of the semiconductor memory device following FIG. 9;

FIG. 11 is a cross-sectional view showing a manufacturing step of the semiconductor memory device following FIG. 10;

FIG. 12 is a cross-sectional view showing a manufacturing step of the semiconductor memory device following FIG. 11;

FIG. 13 is a cross-sectional view showing a semiconductor memory device according to a modification of the first embodiment;

FIG. 14 is a cross-sectional view showing a manufacturing step of the semiconductor memory device according to a second embodiment of the present invention;

FIG. 15 is a cross-sectional view showing a manufacturing step of the semiconductor memory device following FIG. 14;

FIG. 16 is a cross-sectional view showing a manufacturing step of the semiconductor memory device following FIG. 15;

FIG. 17 is a cross-sectional view showing a manufacturing step of the semiconductor memory device following FIG. 16;

FIG. 18 is a cross-sectional view showing a manufacturing step of the semiconductor memory device following FIG. 17;

FIG. 19 is a cross-sectional view showing a manufacturing step of the semiconductor memory device following FIG. 18;

FIG. 20 is a cross-sectional view showing a manufacturing step of the semiconductor memory device following FIG. 19;

FIG. 21 is a cross-sectional view showing a manufacturing step of a semiconductor memory device according to a modification of the second embodiment;

FIG. 22 is a cross-sectional view showing a manufacturing step of the semiconductor memory device following FIG. 21;

FIG. 23 is a cross-sectional view showing a configuration of a selective transistor ST according to a third embodiment of the present invention;

FIG. 24 is a cross-sectional view showing a manufacturing step of the semiconductor memory device according to the third embodiment;

FIG. 25 is a cross-sectional view showing a manufacturing step of the semiconductor memory device following FIG. 24;

FIG. 26 is a cross-sectional view showing a manufacturing step of the semiconductor memory device following FIG. 25;

FIG. 27 is a cross-sectional view showing a manufacturing step of the semiconductor memory device following FIG. 26;

FIG. 28 is a cross-sectional view showing a configuration of a p-channel MOS transistor PMT according to a fourth embodiment of the present invention;

FIG. 29 is a cross-sectional view showing a manufacturing step of the semiconductor memory device according to the fourth embodiment;

FIG. 30 is a cross-sectional view showing a manufacturing step of the semiconductor memory device following FIG. 29;

FIG. 31 is a cross-sectional view showing a manufacturing step of the semiconductor memory device following FIG. 30;

FIG. 32 is a cross-sectional view showing a manufacturing step of the semiconductor memory device following FIG. 31;

FIG. 33 is a cross-sectional view showing a manufacturing step of the semiconductor memory device following FIG. 32;

FIG. 34 is a cross-sectional view showing a manufacturing step of the semiconductor memory device following FIG. 33;

FIG. 35 is a cross-sectional view showing a manufacturing step of the semiconductor memory device following FIG. 34;

FIG. 36 is a cross-sectional view showing a manufacturing step of the semiconductor memory device following FIG. 35;

FIG. 37 is a cross-sectional view showing a manufacturing step of the semiconductor memory device according to a fifth embodiment of the present invention;

FIG. 38 is a cross-sectional view showing a manufacturing step of the semiconductor memory device following FIG. 37;

FIG. 39 is a cross-sectional view showing a manufacturing step of the semiconductor memory device following FIG. 38;

FIG. 40 is a cross-sectional view showing a manufacturing step of the semiconductor memory device following FIG. 39;

FIG. 41 is a cross-sectional view showing a manufacturing step of the semiconductor memory device following FIG. 40;

FIG. 42 is a cross-sectional view showing a manufacturing step of a semiconductor memory device according to a modification of the fifth embodiment;

FIG. 43 is a cross-sectional view showing a manufacturing step of the semiconductor memory device following FIG. 42;

FIG. 44 is a cross-sectional view showing a manufacturing step of the semiconductor memory device following FIG. 43;

FIG. 45 is a cross-sectional view showing a manufacturing step of the semiconductor memory device following FIG. 44;

FIG. 46 is a cross-sectional view showing a manufacturing step of the semiconductor memory device following FIG. 45;

FIG. 47 is a cross-sectional view showing a manufacturing step of the semiconductor memory device following FIG. 46; and

FIG. 48 is a cross-sectional view showing a manufacturing step of the semiconductor memory device following FIG. 47.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

### First Embodiment

A semiconductor memory device according to a first embodiment comprises a memory cell, a metal oxide semiconductor (MOS) transistor, and a resistor element provided on the same semiconductor substrate. The memory cell is formed of a flash memory which is a kind of non-volatile semiconductor memory and electrically rewritable. One of the types including, but not limited to, NAND, NOR, AND, and divided bit-line NOR (DINOR) may be used as the flash memory. In the present embodiment, the description will be made taking a NAND flash memory as an example. The NAND flash memory is a memory from which data is erased by unit of block.

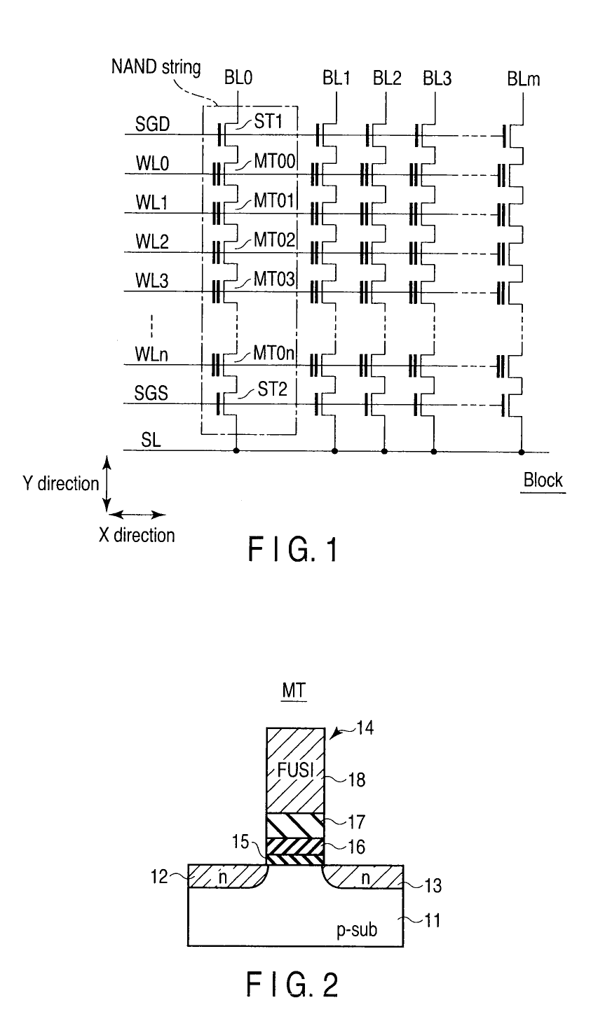

FIG. 1 is a circuit diagram showing a configuration of a block included in a NAND flash memory according to a first embodiment of the present invention.

The block comprises (m+1) NAND strings sequentially arranged along X direction, where m is a natural number equal to or more than 0. Each of the NAND strings has selective transistors ST1 and ST2 and (n+1) memory cell transistors MT, where n is a natural number equal to or more than 0. A drain of the selective transistor ST1 included in each of the (m+1) NAND strings is connected to a corresponding one of the bit lines BL0-BLm, and a gate of the selective transistor ST1 is commonly connected to the selective gate line SGD. A source of the selective transistor ST2 is commonly connected to a source line SL, and a gate of the selective transistor ST2 is commonly connected to a selective gate line SGS.

In each of the NAND strings, the (n+1) memory cell transistors MT are arranged between the source of the selective transistor ST1 and the drain of the selective transistor ST2 such that the current paths are connected in series. That is, the memory cell transistors MT are connected in series in Y direction such that adjacent ones share a diffusion region (source region or a drain region).

Control gate electrodes of the memory cell transistors MT are connected to corresponding ones of word lines WL0-WLn, in the order of increasing distance from the drain. That is, the drain of the memory cell transistor MT connected to the word line WL0 is connected to the source of the selective transistor ST1, and the source of the memory cell transistor MT connected to the word line WLn is connected to the drain of the selective transistor ST2. The memory cell transistors MT of the NAND string connected to the bit line BL0 is defined as MT00, MT01, . . . , and MT0n in the order of increasing distance from the drain.

Each of the word lines WL0-WLn commonly connects control gate electrodes of the memory cell transistors MT of the NAND strings in each block. That is, the control gate electrodes of the memory cell transistors MT in the same row in each block are connected to the same word line WL. The (m+1) memory cell transistors MT connected to the same word line WL are handled as one page, and data writing and reading is performed per page.

Each of bit lines BL0-BLm commonly connects the drains of the selective transistors ST1 of a plurality of blocks. That is, NAND strings in the same column in different blocks are connected to the same bit line BL.

FIG. 2 shows a cross-sectional view showing a configuration of a memory cell transistor MT. The memory cell transistor MT of the present embodiment is a Metal Oxide Nitride Oxide Semiconductor (MONOS) memory cell. Further, the memory cell transistor MT is provided in a memory region of a semiconductor substrate 11.

One of substrates such as a p-type semiconductor substrate, a semiconductor substrate having a p-type well, and a Silicon On Insulator (SOI) substrate having a p-type semiconductor layer may be used as the semiconductor substrate 11 of p-type conductivity type. Two n⁺-type diffusion regions (source/drain regions) 12 and 13, formed to be apart from each other, are provided in the p-type semiconductor substrate (p-sub) 11. The n⁺ diffusion regions 12 and 13 are formed by introducing a highly concentrated n⁺-type impurity (such as phosphorous (P) and arsenic (As)) into the p-type semiconductor substrate 11.

A stacked gate structure 14 is formed on a channel region between the n⁺-type diffusion regions 12 and 13. More specifically, the stacked gate structure 14 is formed of a tunnel insulation film 15, a charge storage layer 16, a block insulation film 17, and a control gate electrode 18, sequentially stacked on the p-type semiconductor substrate 11.

Silicon (Si), for example, is used as the p-type semiconductor substrate 11. Silicon oxide, for example, is used as the tunnel insulation film 15. Silicon nitride, for example, is used as the charge storage layer 16.

A stacked film of aluminum oxide (such as Al₂O₃) and silicon nitride or a stacked film of aluminum oxide and titan nitride, for example, is used as the block insulation film 17. A nitride included in the block insulation film 17 is provided to prevent aluminum from diffusing into the silicon as the control gate electrode 18. By providing silicon nitride, for example, between the aluminum oxide and the control gate electrode 18, reaction between the aluminum and the silicon can be prevented, and thereby deterioration in properties of the block insulation film 17 can be prevented.

The control gate electrode 18 of the present embodiment is formed of a fully silicided (FUSI) gate electrode obtained by fully siliciding a polysilicon electrode. Metals such as nickel (Ni), cobalt (Co), titan (Ti), tungsten (W) and molybdenum (Mo) can be used to be reacted with the polysilicon. By fully siliciding the control gate electrode 18, the work function of the control gate electrode 18 increases, and thereby the barrier height of the interface between the control gate electrode 18 and the block insulation film 17 increases. As a result, the leak current from the control gate electrode 18 to the block insulation film 17 can be decreased, and thereby the data erasure properties of the memory cell transistor MT can be improved.

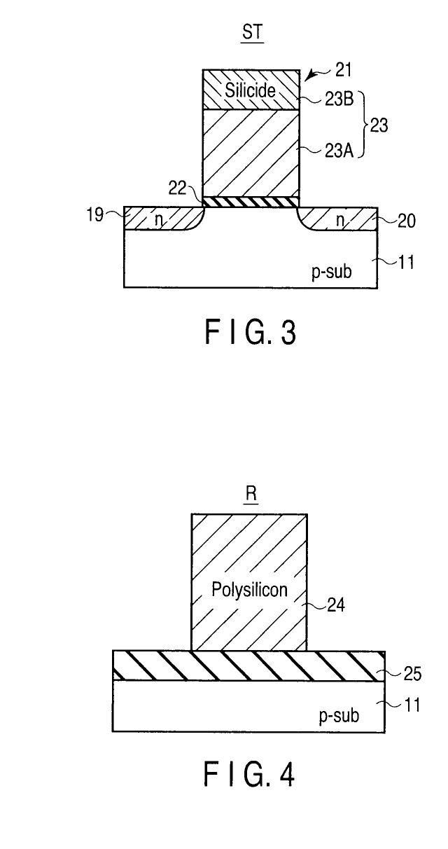

FIG. 3 is a cross-sectional view showing a configuration of a selective transistor ST. The selective transistor ST is formed of an n-channel MOS transistor. The selective transistor ST is provided in a peripheral transistor region on the semiconductor substrate 11 on which the memory cell transistor MT is formed.

In the p-type semiconductor substrate 11, two n⁺-type diffusion regions (source/drain regions) 19 and 20, formed apart from each other, are provided. The n⁺-type diffusion regions 19 and 20 are formed by introducing an n⁺-type impurity (such as phosphorous (P) and arsenic (As)) into the p-type semiconductor substrate 11.

A gate structure 21 is formed on a channel region between the n⁺-type diffusion regions 19 and 20. More specifically, the gate structure 21 is formed of a gate insulation film 22 and a gate electrode 23 sequentially stacked on the p-type semiconductor substrate 11. Silicon oxide, for example, is used as the gate insulation film 22.

The gate electrode 23 of the present embodiment is formed by partially siliciding a polysilicon electrode. That is, the gate electrode 23 is formed of a polysilicon electrode 23A which is provided on a gate insulation film 22 and not silicided, and a silicide electrode 23B formed by partially siliciding an upper portion of polysilicon.

When a gate electrode of a selective transistor ST is fully silicided, the work function of the gate electrode increases, which causes increase in threshold voltage. When the gate electrode is formed only of polysilicon (by not being silicided at all), the resistance of the gate electrode increases, and thereby the operation rate of the selective transistor ST decreases. In the present embodiment, by using the partially silicided gate electrode 23 as a selective transistor ST, variation in threshold voltage can be suppressed, and the operation rate can be improved.

FIG. 4 shows a cross-sectional view showing a configuration of a resistor element (R) 24. The semiconductor memory device of the present embodiment comprises the resistor element 24. The resistor element 24 is provided in a resistive region on the semiconductor substrate 11 on which the memory cell transistor MT and the selective transistor ST are formed. An element isolation insulation film 25 is formed in the semiconductor substrate 11. A resistor element 24, which uses polysilicon as a resistor, is formed on the element isolation insulation film 25.

When the resistor element is silicided, the resistance decreases, which inevitably causes increase in element area in order to obtain a desired resistance value. In order to prevent this, the resistor element 24 of the present embodiment is formed of polysilicon which is not silicided at all. Thereby, the element area of the resistor element 24 can be decreased, which results in decrease in area of the semiconductor memory device.

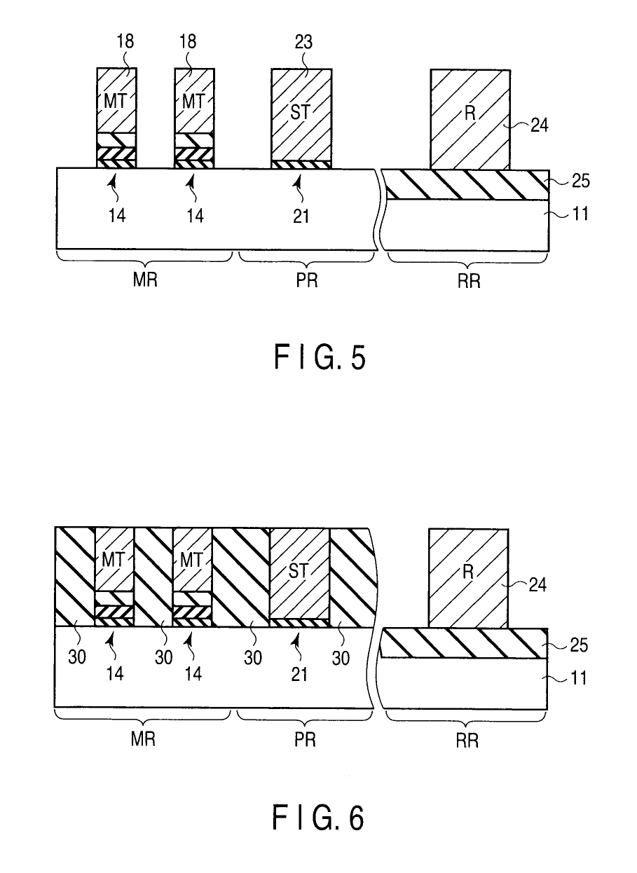

A manufacturing method of the semiconductor memory device according to the first embodiment will now be described with reference to the accompanying drawings. The memory cell region (MR) and the peripheral transistor region (PR) shown in FIG. 5 correspond to the cross section in the bit line direction of the NAND strings MT01-ST1 shown in FIG. 1.

As shown in FIG. 5, an element isolation insulation film 25 is formed in the resistive region (RR) of the semiconductor substrate 11. A stacked gate structure 14 included in the memory cell transistor MT is formed by sequentially depositing the tunnel insulation film 15, the charge storage layer 16, the block insulation film 17, and the control gate electrode 18 on the semiconductor substrate 11 in the memory region (MR), and patterning them in desired shapes. A gate structure 21 included in the selective transistor ST is formed by depositing the gate insulation film 22 and the gate electrode 23 on the semiconductor substrate 11 in the peripheral transistor region (PR), and patterning them in desired shapes.

A resistor element 24 having a desired shape is formed by sequentially depositing a polysilicon layer on the element isolation insulation film 25 of the resistive region (RR) and patterning the polysilicon layer. In this state, both of the control gate electrode 18 and the gate electrode 23 are formed of polysilicon.

The control gate electrode 18, the gate electrode 23, and the resistor element 24 may be simultaneously formed by depositing a polysilicon layer on the semiconductor substrate 11 and processing it through RIE, for example. Thereby, the control gate electrode 18, the gate electrode 23, and the resistor element 24 can be formed with a small number of steps.

Subsequently, a diffusion region (source/drain region) is formed by introducing impurity into the semiconductor substrate 11. The diffusion region is not shown in FIG. 5 and other drawings showing the subsequent manufacturing steps.

As shown in FIG. 6, an interlayer insulation layer 30 is embedded between gate electrodes of a transistor (i.e., between the stacked gate structures 14, between the gate structures 21, and between the stacked gate structure 14 and the gate structure 21), and the upper surface of the interlayer insulation layer 30 is aligned with the upper surface of each of the stacked gate structure 14 and the gate structure 21 using the RIE method, for example. Although the interlayer insulation layer 30 is not shown in the periphery (resistive region) of the resistance element 24, the interlayer insulation layer 30 may be formed on side surfaces of the resistor element 24. Silicon oxide, for example, is used as the interlayer insulation layer 30.

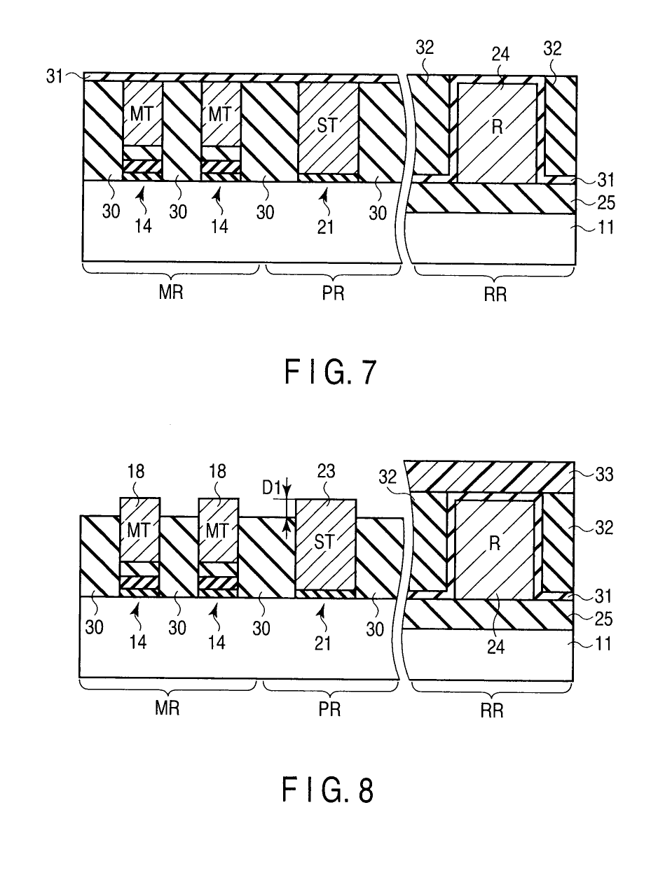

As shown in FIG. 7, a barrier film 31 is deposited on the entire surface of the device through chemical vapor deposition (CVD). As a result of this step, the barrier film 31 continuously covers the control gate electrode 18, the gate electrode 23, and the interlayer insulation layer 30, and also covers the upper surface and the side surface of the resistor element 24. Silicon nitride, for example, is used as the barrier film 31. After that, an interlayer insulation layer 32 is embedded between the resistor elements 24 on the barrier film 31. Silicon oxide, for example, may be used as the interlayer insulation layer 32.

As shown in FIG. 8, the resistive region is covered with the resist layer 33 using the lithography method. After that, the barrier film 31 formed in the memory region and the peripheral transistor region is removed using the resist layer 33 as a mask. Further, the interlayer insulation layer 30 of the memory region and the peripheral transistor region is etched back to a first depth D1 to expose an upper portion of each of the control gate electrode 18 and the gate electrode 23. After that, the resist layer 33 is removed.

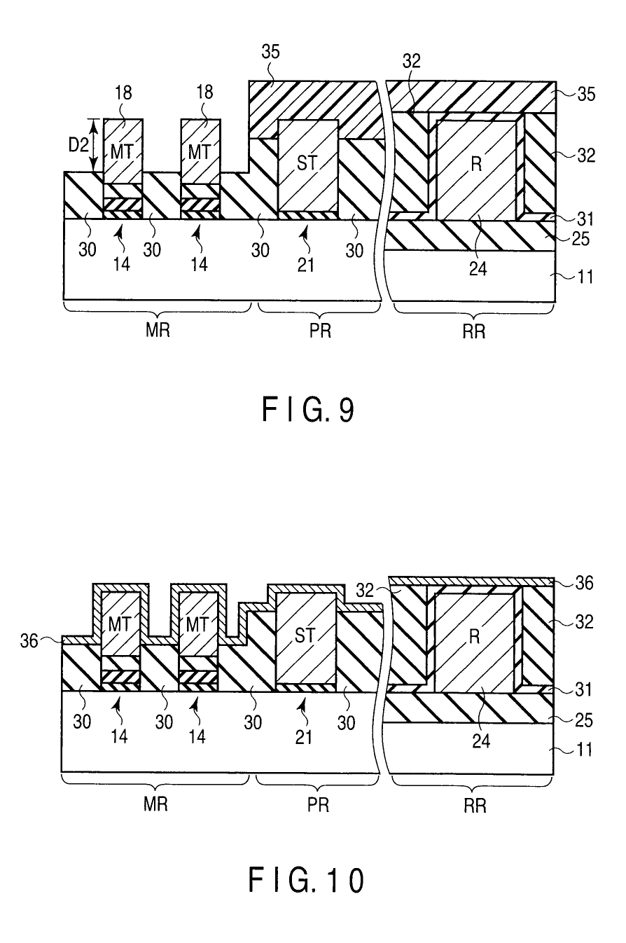

As shown in FIG. 9, a resist layer 35 is formed on the interlayer insulation layer 30 of the peripheral transistor region and the gate structure 21, through lithography. Further, the interlayer insulation layer 30 is etched back to a second depth D2 greater than the first depth D1 using the resist layer 35 as a mask, to further deeply expose the upper portion of the control gate electrode 18. By thus etching back the interlayer insulation layer 30 in the memory region more deeply than the interlayer insulation layer 30 in the peripheral transistor region, a difference in height is generated between the interlayer insulation layer 30 in the memory region and the interlayer insulation layer 30 in the peripheral transistor region. After that, the resist layer 35 is removed.

The first depth D1 is equal to or smaller than the depth from the upper surface of the gate electrode 23 to the intermediate position of the gate electrode 23, for example. The second depth D2 is larger than the depth from the upper surface of each of the control gate electrode 18 to the intermediate position of the control gate electrode 18, for example. The above-described depths D1 and D2 are just examples and any depths satisfying the relationship that the second depth D2 is greater than the first depth D1 can be used.

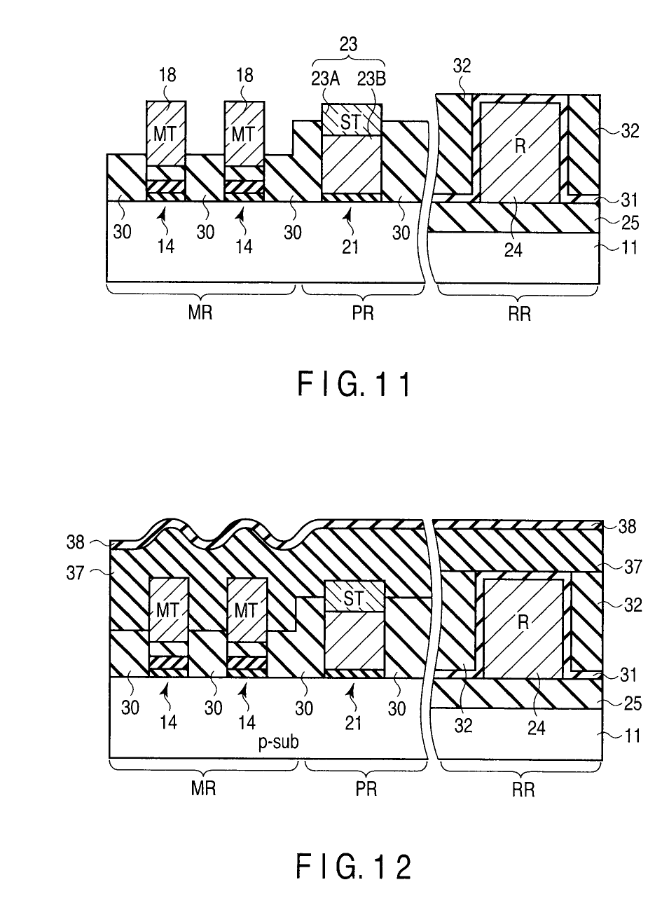

As shown in FIG. 10, a metal film 36 formed of cobalt (Co), for example, is stacked on the upper surface and the side surfaces of each of the stacked gate structure 14 and the gate structure 21 through spattering, for example. Thereby, the metal film 36 deeply adheres to the side surfaces of the stacked gate structure 14, compared to the side surfaces of the gate structure 21. In this state, the device is subjected to heat treatment to cause reaction between the metal film 36 and the polysilicon (the control gate electrode 18 and the gate electrode 23). Thereby, as shown in FIG. 11, the fully silicided control gate electrode 18 is formed.

Since the side surfaces of the gate electrode 23 do not contact the metal film 36 except the upper portion, only a part of the gate electrode 23 is silicided. As a result, the upper portion of the gate electrode 23 is silicided, and the gate electrode 23 formed of a polysilicon electrode 23A and a silicide electrode 23B is formed. The resistor element 24 is not silicided, because The resistor element 24 is not contacting the metal film 36. After that, the remaining metal film 36 is wet-etched.

As shown in FIG. 12, an interlayer insulation layer 37 formed of silicon oxide, for example, is deposited on the entire surface of the device through CVD, for example. After that, a stopper film 38 used as a stopper in the subsequent planarization process is deposited on the interlayer insulation layer 37 through CVD, for example. Due to a difference in height generated in the interlayer insulation layer 30, a difference in height is generated between the memory region and the peripheral transistor region in the stopper film 38. Silicon nitride, for example, is used as the stopper film 38. Thus, the semiconductor memory device of the present embodiment is formed.

As described above, according to the present embodiment, a memory cell transistor MT having the fully silicided control gate electrode 18, the selective transistor ST having the partially silicided gate electrode 23, and the resistor element 24 formed of polysilicon can be formed on the same substrate. Thereby, in the memory cell transistor MT, a leak current to the block insulation film 17 can be decreased, and thereby data erasure properties can be improved. In the selective transistor ST, variation in threshold voltage can be suppressed and the operation rate can be improved. In the resistor element 24, the element area can be decreased.

Further, merely by performing the step of depositing the metal film 36 once and the heat treatment step once, the fully silicided control gate electrode 18 and the partially silicided gate electrode 23 can be simultaneously formed. Thereby, the manufacturing cost can be decreased. Further, the resistor element 24 can be prevented from being silicided in this silicidation process.

### Modification of First Embodiment

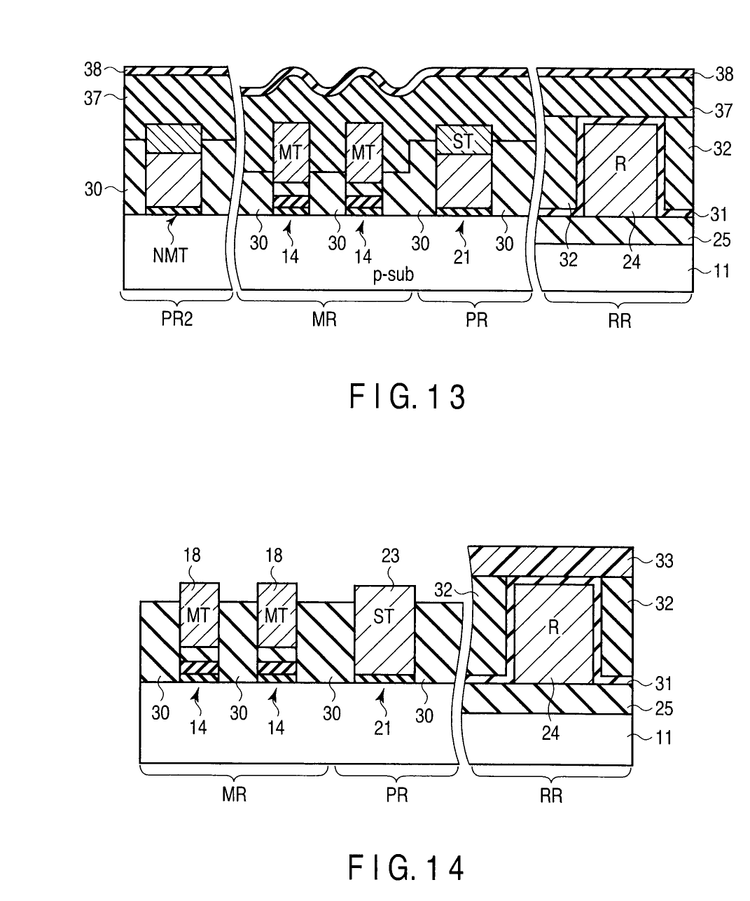

FIG. 13 is a cross-sectional view showing a modification of the semiconductor device according to the first embodiment. In the first embodiment, the memory region and the peripheral transistor region are adjacent to each other. In addition to this configuration, a peripheral transistor region 2 which is adjacent to the memory region and the peripheral transistor region is formed in the modification of the first embodiment.

An n-channel MOS transistor NMT having the same configuration as the selective transistor ST is arranged in the peripheral transistor region 2. In the peripheral transistor region 2 which is adjacent to the memory region, an n-channel MOS transistor NMT having a configuration similar to that of the selective transistor ST can be manufactured by a manufacturing method similar to that of the first embodiment.

### Second Embodiment

In a second embodiment, a semiconductor memory device comprising a memory cell transistor MT having a FUSI gate electrode, a selective transistor ST having a partially silicided gate electrode, and a resistor element formed of polysilicon, is manufactured by using a manufacturing method different from that of the first embodiment.

The manufacturing method of the semiconductor memory device according to the second embodiment will now be described with reference to the accompanying drawings. The manufacturing steps from FIG. 5 to FIG. 7 are the same as those of the first embodiment. Following those steps, as shown in FIG. 14, the resistive region is covered with a resist layer 33 through lithography. After that, the barrier film 31 formed in the memory region and the peripheral transistor region is removed using the resist layer 33 as a mask. After that, the interlayer insulation layer 30 formed in the memory region and the peripheral transistor region is etched back to the same depth. When the upper surface of the control gate electrode 18 and the upper surface of the gate electrode 23 have the same height, the upper portion of each of the control gate electrode 18 and the gate electrode 23 is exposed by the same depth. The depth of etching back is set smaller the height of the intermediate position of the control gate electrode 18 or the gate electrode 23. After that, the resist 33 is removed.

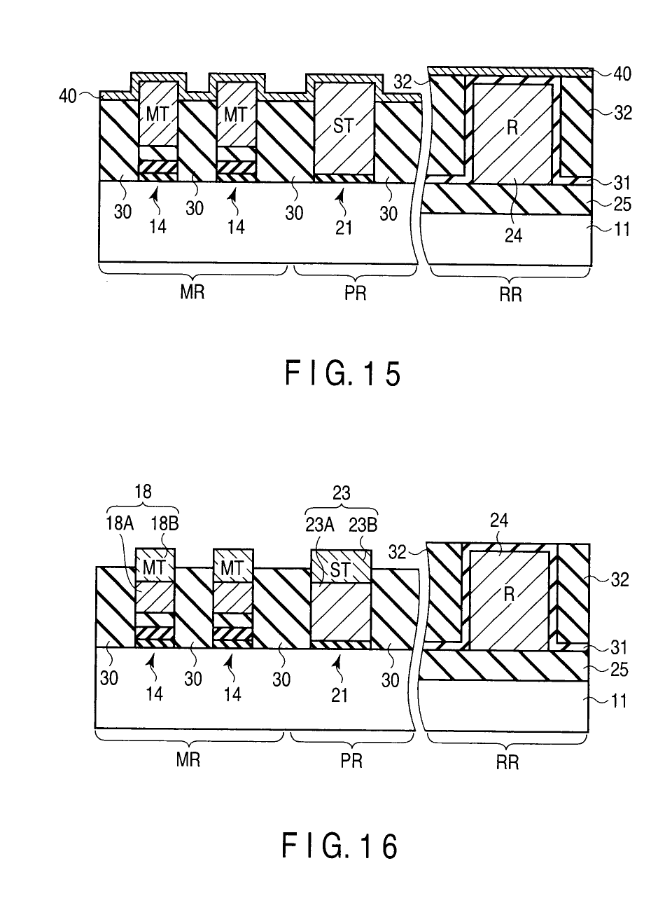

As shown in FIG. 15, a metal film 40 formed of cobalt (Co), for example, is deposited on an upper surface and side surfaces of each of the stacked gate structure 14 and the gate structure 21 through spattering, for example. In this state, the device is subjected to heat treatment to cause reaction between the metal film 40 and the polysilicon (the control gate electrode 18 and the gate electrode 23). Thereby, as shown in FIG. 16, the upper portion of the gate electrode 23 is silicided, and a gate electrode 23 formed of a polysilicon electrode 23A and a silicide electrode 23B is formed. Similarly, the upper portion of the control gate electrode 18 is silicided and a control gate electrode 18 formed of a polysilicon electrode 18A and a silicide 18B is formed. Not contacting the metal film 36, the resistor element 24 is not silicided. That is, in this state, the control gate electrode 18 is partially silicided. After that, the remaining metal film 40 is wet-etched.

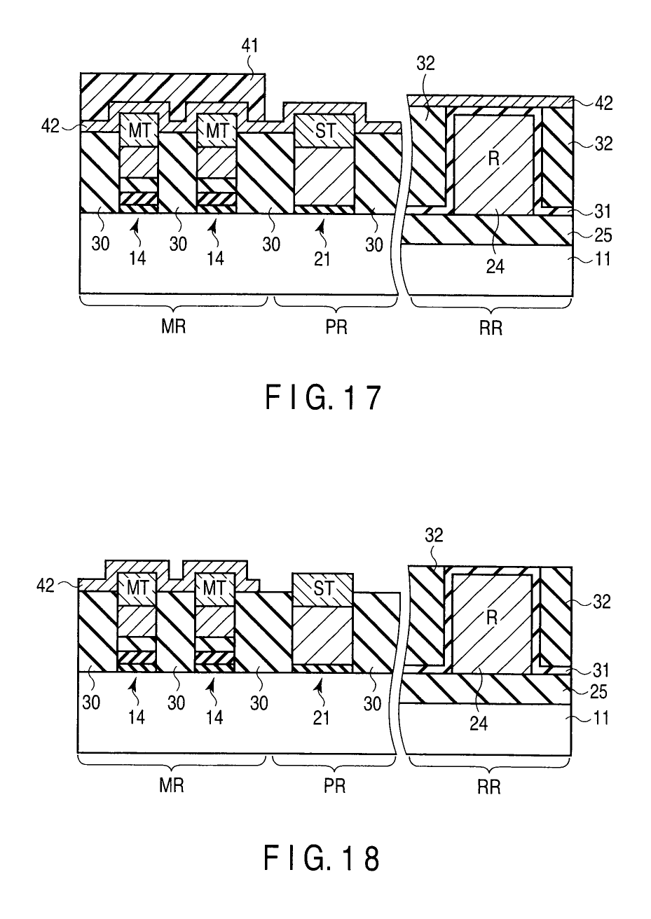

As shown in FIG. 17, a metal film 42 formed of cobalt (Co), for example, is deposited on an upper surface and side surfaces of the stacked gate structure 14 through spattering, for example. After that, a resist layer 41 is formed through lithography to cover the upper portion of the stacked gate structure 14 in the memory region.

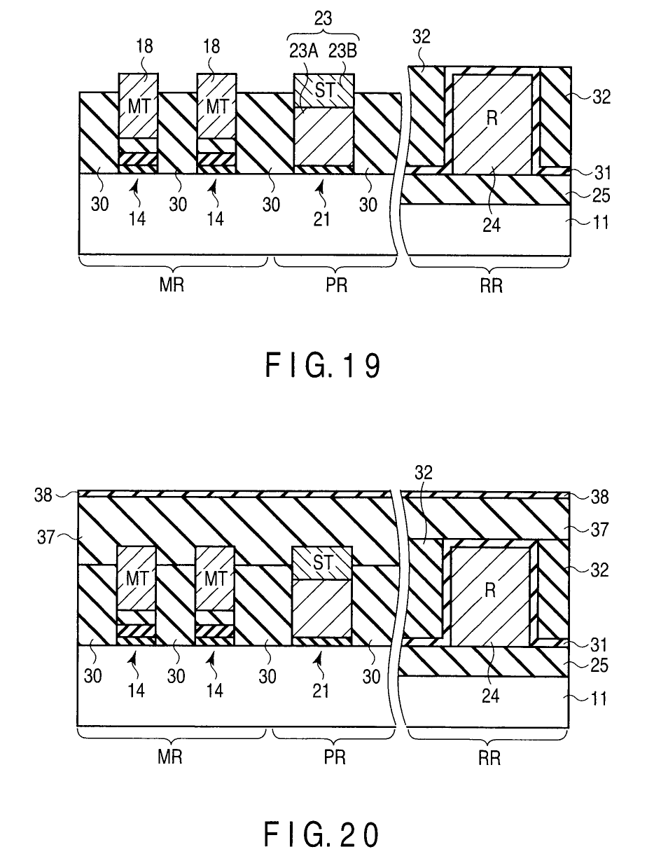

As shown in FIG. 18, the metal film 42 in the peripheral transistor region and the resistive region is removed, and then the resist layer 41 is removed. In this state, the device is subjected to heat treatment to cause reaction between the metal film 42 and the control gate electrode 18. That is, the control gate electrode 18 in the memory region is fully silicided by being silicided twice, while the gate electrode 23 is silicided once and only the upper portion of the gate electrode 23 is partially silicided. Thereby, as shown in FIG. 19, the fully silicided control gate electrode 18 is formed. After that, the remaining metal film 42 is wet-etched.

The number of times of siliciding the memory region may be more than two. Further, the number of times of siliciding the peripheral transistor region may be any number smaller than the number of times of siliciding the memory region, as long as the gate electrode 23 is not fully silicided.

As shown in FIG. 20, an interlayer insulation layer 37 formed of silicon oxide, for example, is deposited on the entire surface of the device through CVD, for example. After that, a stopper film 38 to be used as a stopper in the subsequent planarization process is deposited on the interlayer insulation layer 37 through CVD, for example. Thus, the semiconductor memory device of the present embodiment is formed.

As described above, according to the present embodiment, a semiconductor memory device comprising a memory cell transistor MT having a FUSI gate electrode, a selective transistor ST having a partially silicided gate electrode, and a resistor element formed of polysilicon can be formed by using a manufacturing method different from that of the first embodiment.

Further, in the present embodiment, a difference in height is not generated between the memory region and the peripheral transistor region. A process margin of forming a wiring, for example, provided in an upper layer of each of the memory cell transistor MT and the selective transistor ST increases.

### Modification of Second Embodiment

In the modification of the second embodiment, a semiconductor memory device comprising a memory cell transistor MT having a FUSI gate electrode, a selective transistor ST having a partially silicided gate electrode, and a resistor element formed of polysilicon is manufactured by partially changing the manufacturing process of the second embodiment.

The manufacturing steps up to FIG. 16 are the same as those of the second embodiment. Following those steps, as shown in FIG. 21, a resist layer 41 is formed in the peripheral transistor region and the resistive region through lithography to cover the upper portion of the gate structure 21 of the selective transistor ST through lithography. After that, the interlayer insulation layer 30 is etched back to a second depth D2 smaller than the height of the lower surface of the silicide 18B using the resist layer 41 as a mask, and thereby the upper portion of the polysilicon electrode 18A is partially exposed. The second depth D2 may be any depth greater than the height of the lower surface of the silicide 18B, irrespective of whether the depth is greater or smaller than the height of the upper surface of the block insulation film 17.

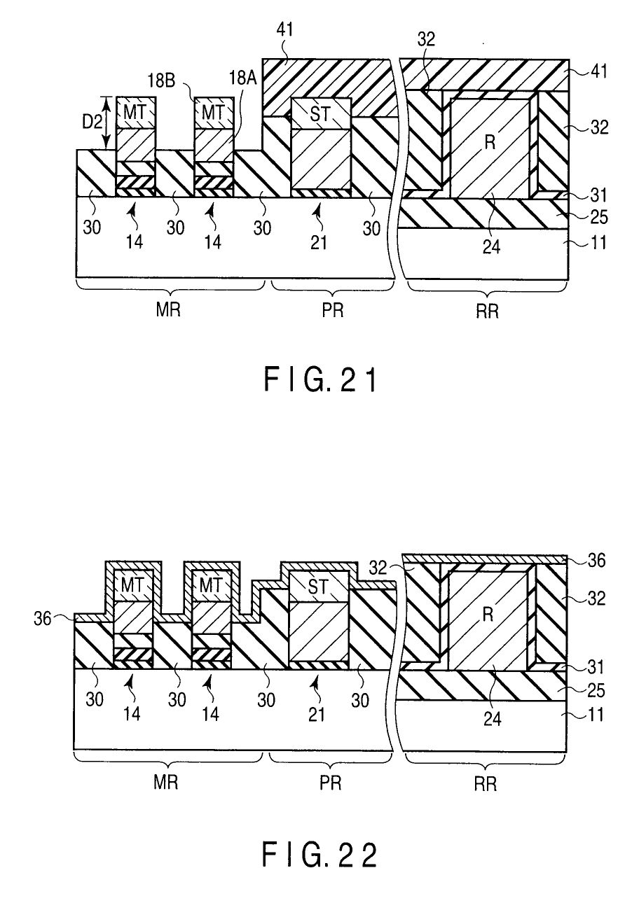

As shown in FIG. 22, the resist layer 41 is removed, and then a metal film 42 formed of cobalt (Co), for example, is deposited through spattering, for example. In this state, the device is subjected to heat treatment to cause reaction between the metal film 42 and the control gate electrode 18. That is, the control gate electrode 18 in the memory region is fully silicided by being silicided twice, while the gate electrode 23 is silicided once and only the upper portion of the gate electrode 23 is partially silicided.

In the modification of the second embodiment, in addition to the same effect as can be obtained from the second embodiment, an amount of the gate electrode 23 siliciding can be easily controlled. This modification is effective when an amount of the upper portion of the gate electrode 23 siliciding needs to be decreased, for example.

### Third Embodiment

In a third embodiment, both of a control gate electrode 18 of a memory cell transistor MT and a gate electrode 23 of a selective transistor ST are formed of FUSI gate electrodes.

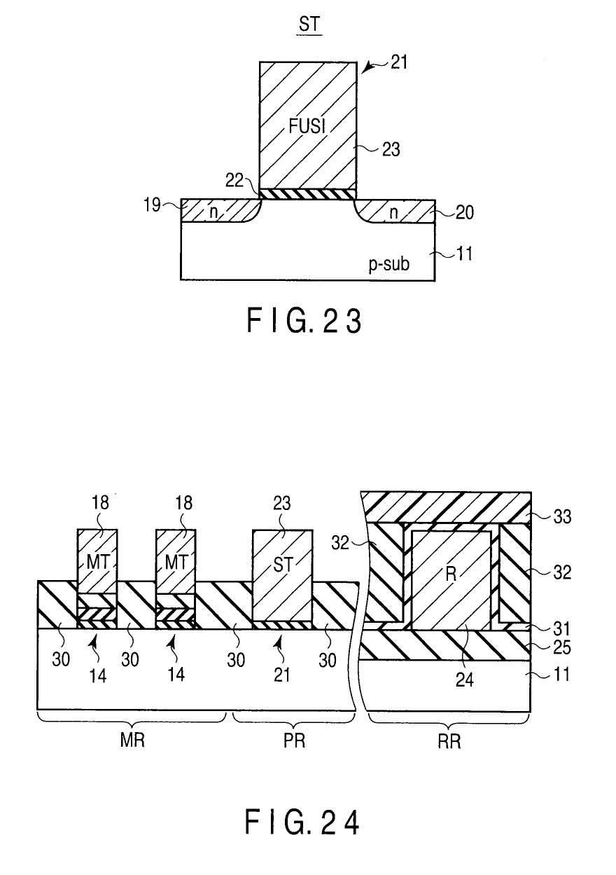

FIG. 23 is a cross-sectional view showing a configuration of a selective transistor ST according to the third embodiment of the present invention. The configurations of the memory cell transistor MT and a resistive element 24 are the same as those shown in FIGS. 2 and 4 of the first embodiment.

The selective transistor ST is formed of an n-channel MOS transistor. Further, the selective transistor ST is provided on the semiconductor substrate 11 on which the memory cell transistor MT is formed.

Two n⁺-type diffusion regions 19 and 20, formed apart from each other, are provided in the p-type semiconductor substrate 11. A gate structure 21 is formed on a channel region between the n⁺-type diffusion regions 19 and 20. More specifically, the gate structure 21 is formed by sequentially stacking a gate insulation film 22 and the gate electrode 23 on the p-type semiconductor substrate 11. Further, the gate electrode 23 of the present embodiment is formed of a FUSI gate electrode formed by fully siliciding a polysilicon electrode. Metals such as nickel (Ni), cobalt (Co), titan (Ti), tungsten (W), and molybdenum (Mo) are used to be reacted with the polysilicon.

A manufacturing method of the semiconductor memory device according to the third embodiment will now be described with reference to the accompanying drawings. The manufacturing steps from FIG. 5 to FIG. 7 are the same as those of the first embodiment.

Following those steps, as shown in FIG. 24, the resistive region is covered with a resist layer 33 through lithography. After that, the barrier film 31 formed in the memory region and the peripheral transistor region is removed using the resist layer 33 as a mask. After that, the interlayer insulation layer 30 formed in the memory region and the peripheral transistor region is etched back to the same depth to expose a lower portion of the control gate electrode 18 and an intermediate portion of the gate electrode 23. After that, the resist layer 33 is removed.

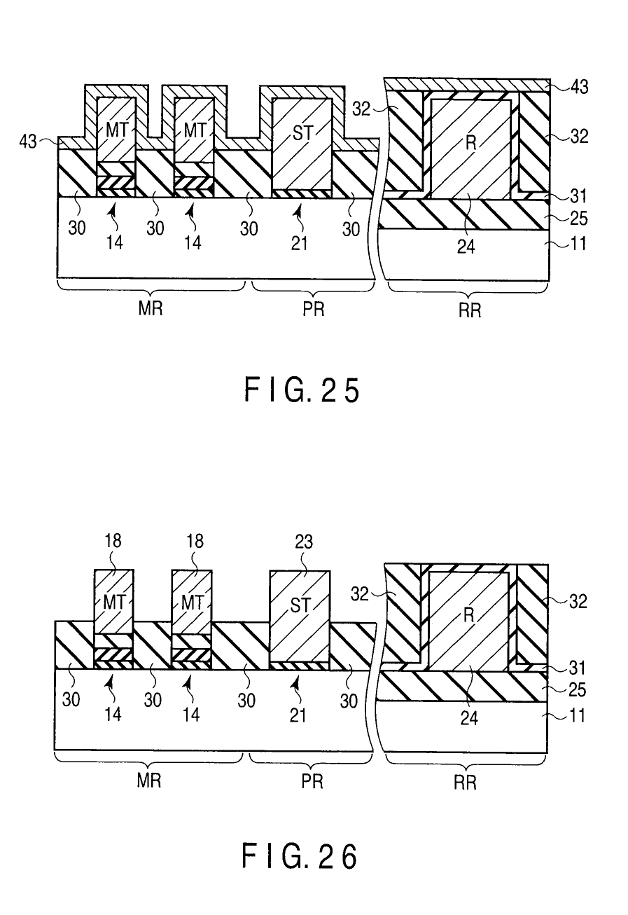

As shown in FIG. 25, a metal film 43 formed of cobalt (Co), for example, is deposited on an upper surface and side surfaces of each of the stacked gate structure 14 and the gate structure 21 through spattering, for example. In this state, the device is subjected to heat treatment to cause reaction between the metal film 43 and the polysilicon (control gate electrode 18 and the gate electrode 23). Thereby, as shown in FIG. 26, the fully silicided control gate electrode 18 and the gate electrode 23 are formed. Not contacting the metal film 36, the resistor element 24 is not silicided. After that, the remaining metal film 43 is wet-etched.

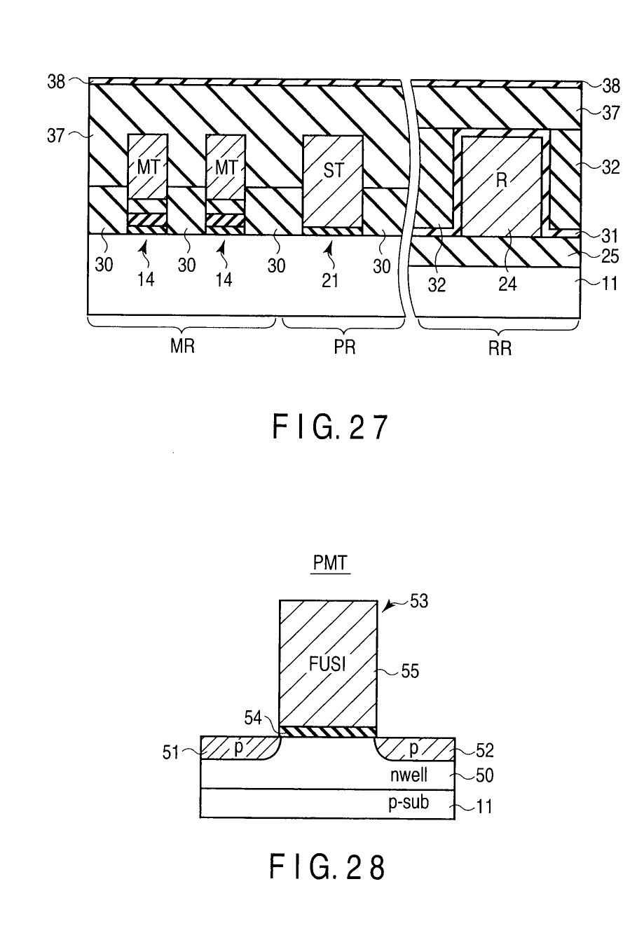

As shown in FIG. 27, the interlayer insulation layer 37 formed of silicon oxide, for example, is deposited on the entire surface of the device through CVD, for example. After that, a stopper film 38 used as a stopper in the subsequent planarization step is deposited on the interlayer insulation layer 37 through CVD, for example. Thus, the semiconductor memory device of the present embodiment is formed.

As described above, according to the present embodiment, the memory cell transistor MT having the FUSI control gate electrode 18, the selective transistor ST having the FUSI gate electrode 23, and the resistor element 24 formed of polysilicon can be formed on the same substrate.

Further, by performing the step of depositing the metal film 43 once and the heat treatment step once, the FUSI control gate electrode 18 and the FUSI gate electrode 23 can be simultaneously formed. Thereby, the manufacturing cost can be decreased. Further, it is also possible to prevent the resistor element 24 from being silicided in this silicidation process.

### Fourth Embodiment

A semiconductor memory device according to a fourth embodiment of the present invention comprises a memory cell transistor MT having a FUSI control gate electrode 18, a selective transistor ST having a partially silicided gate electrode 23, and a resistor element 24 formed of polysilicon, as in the case of the first embodiment. In addition to these elements, the semiconductor memory device according to the fourth embodiment comprises a p-channel MOS transistor PMT having a FUSI gate electrode on the same substrate.

FIG. 28 is a cross-sectional view showing a configuration of a p-channel MOS transistor PMT according to the fourth embodiment of the present invention. The configurations of a memory cell transistor MT, the selective transistor ST formed of an n-channel MOS transistor, and a resistor element 24 are the same as those of FIGS. 2-4 shown in the first embodiment.

The p-channel MOS transistor PMT is provided on a semiconductor substrate 11 on which the memory cell transistor MT, for example, is formed. An n-type semiconductor region (n-type well) 50 is provided in the p-type semiconductor substrate 11. The n-type well (nwell) 50 is formed by introducing low-concentrated n-type impurity (such as phosphorous (P) and arsenic (As)) into the p-type semiconductor substrate 11.

In the n-type well 50, two p⁺-type diffusion regions (source/drain regions) 51 and 52, formed apart from each other, are provided. The p⁺-type diffusion regions 51 and 52 are formed by introducing a high-concentrated p⁺-type impurity (such as boron (B)) into the n-type well 50.

A gate structure 53 is formed on a channel region between the p⁺-type diffusion regions 51 and 52. More specifically, the gate structure 53 is formed by sequentially stacking a gate insulation film 54, a gate electrode 44 on the n-type well 50. Silicon oxide, for example, is used as the gate insulation film 54.

The gate electrode 55 of the present embodiment is formed of a FUSI gate electrode formed by fully siliciding a polysilicon electrode. Metals such as nickel (Ni), cobalt (Co), titan (Ti), tungsten (W), and molybdenum (Mo) are used to be reacted with the polysilicon. By fully siliciding the gate electrode 55 of the p-channel MOS transistor PMT, a buried-channel transistor PMT can be formed.

The manufacturing method of the semiconductor memory device according to the fourth embodiment will now be described with reference to the accompanying drawings.

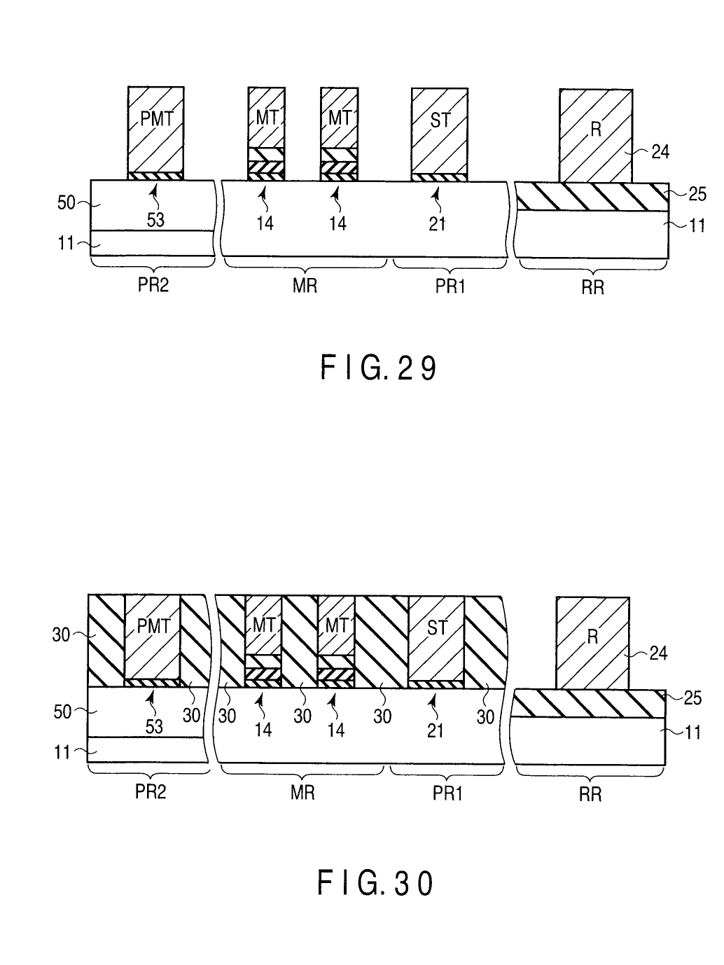

As shown in FIG. 29, an n-type well 50 is formed by introducing a low-concentrated n-type impurity into the semiconductor substrate 11 in the peripheral transistor region 2 (PR2). After that, a gate insulation film 54 and a gate electrode 55 are sequentially stacked on the n-type well 50, and are patterned in desired shapes through lithography and RIE to form a gate structure 53 included in a p-channel MOS transistor PMT. A stacked gate structure 14 included in the memory cell transistor MT is formed by sequentially depositing a tunnel insulation film 15, a charge storage layer 16, a block insulation film 17, and a control gate electrode 18 on the semiconductor substrate 11 of the memory region (MR), and patterning them in desired shapes. The gate electrode 55 is doped with an n-type impurity (such as phosphorous (P) and arsenic (As)).

A gate structure 21 included in a selective transistor ST is formed by sequentially depositing a gate insulation film 22 and a gate electrode 23 on the semiconductor substrate 11 in the peripheral transistor region 1 (PR1) and patterning them in desired shapes. The gate electrode 23 is doped with an n-type impurity (such as phosphorous (P) and arsenic (As)), as in the case of the gate electrode 55.

An element isolation insulation film 25 is formed in the semiconductor substrate 11 in the resistive region (RR). By depositing a polysilicon layer on the element isolation insulation layer 25 and patterning the polysilicon layer, a resistor element 24 with a desired shape is formed. In this state, the control gate electrode 18, the gate electrode 23, and the gate electrode 55 are formed of polysilicon.

The control gate electrode 18, the gate electrode 23, the resistor element 24, and the gate electrode 55 may be simultaneously formed by depositing a polysilicon layer on the semiconductor substrate 11 and processing it through RIE, for example. As a result, the control gate electrode 18, the gate electrode 23, the resistor element 24, and the gate electrode 55 can be formed with a small number of steps.

Subsequently, by introducing an impurity into the semiconductor substrate 11 and the n-type well 50, a diffusion region (source/drain region) is formed. The diffusion region is not shown in FIG. 29 or the drawings showing the manufacturing steps which will be described below.

As shown in FIG. 30, an interlayer insulation layer 30 is embedded between the gate electrodes of the transistor (between the stacked gate structures 14, between the gate structures 21, between the stacked gate structure 14 and the gate structure 21, and in the sides of the gate structure 53), and the upper surface of the interlayer insulation layer 30 is aligned with the upper surface of each of the stacked gate structure 14 and the gate structure 21 through RIE, for example. Although the interlayer insulation layer 30 is not shown in the resistive region (in the periphery of the resistor element 24), the interlayer insulation layer 30 may be formed on side surfaces of the resistor element 24. Silicon oxide, for example, is used as the interlayer insulation layer 30.

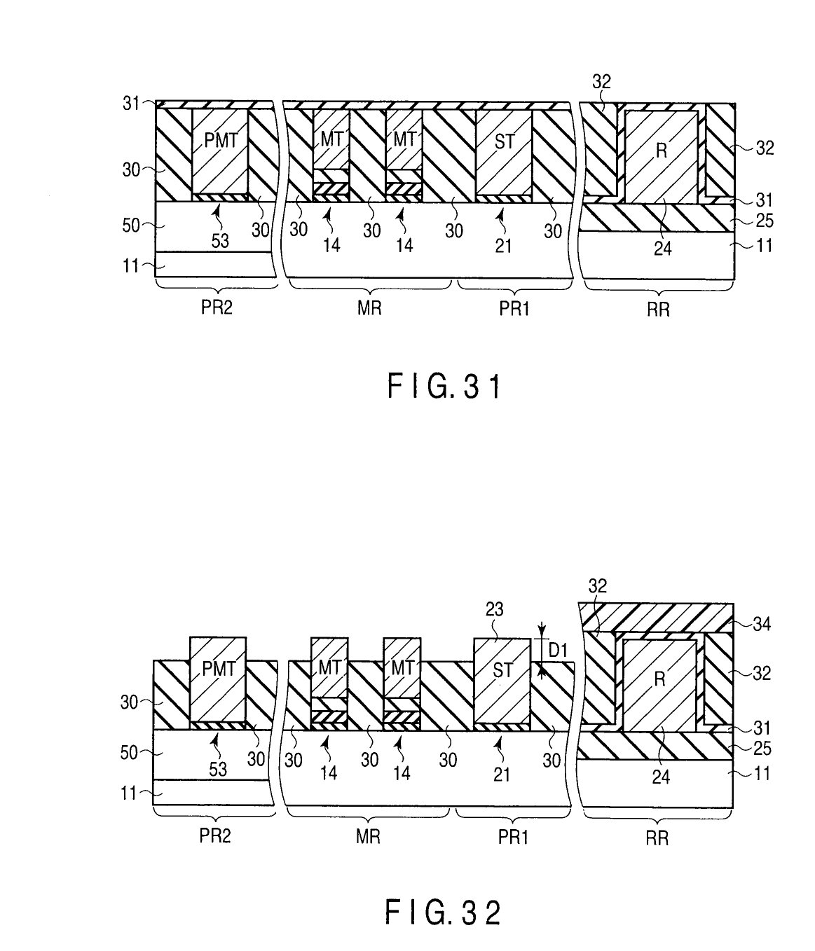

As shown in FIG. 31, a barrier film 31 is deposited on the entire surface of the device through CVD, for example. As a result, the barrier film 31 continuously covers the upper surface of the control gate electrode 18, the upper surface of gate electrode 23, and the upper surface of the interlayer insulation layer 30, and also covers an upper surface of the gate electrode 55 and an upper surface and side surfaces of the resistor element 24. Silicon nitride, for example, is used as the barrier film 31. After that, an interlayer insulation layer 32 is embedded between the resistor elements 24 on the barrier film 31. Silicon oxide, for example, is used as the interlayer insulation layer 32. The barrier film 31 may be formed via the interlayer insulation layer 30 on side surfaces of the gate electrode 55.

As shown in FIG. 32, the resistive region is covered with a resist layer 33 through lithography. After that, the barrier film 31 is etched using the resist layer 33 as a mask to remove the barrier film 31 formed in the memory region and the peripheral transistor regions 1 and 2. After that, the interlayer insulation layer 30 formed in the memory region and the peripheral transistor regions 1 and 2 is etched back to a first depth D1. After that, the resist layer 34 is removed.

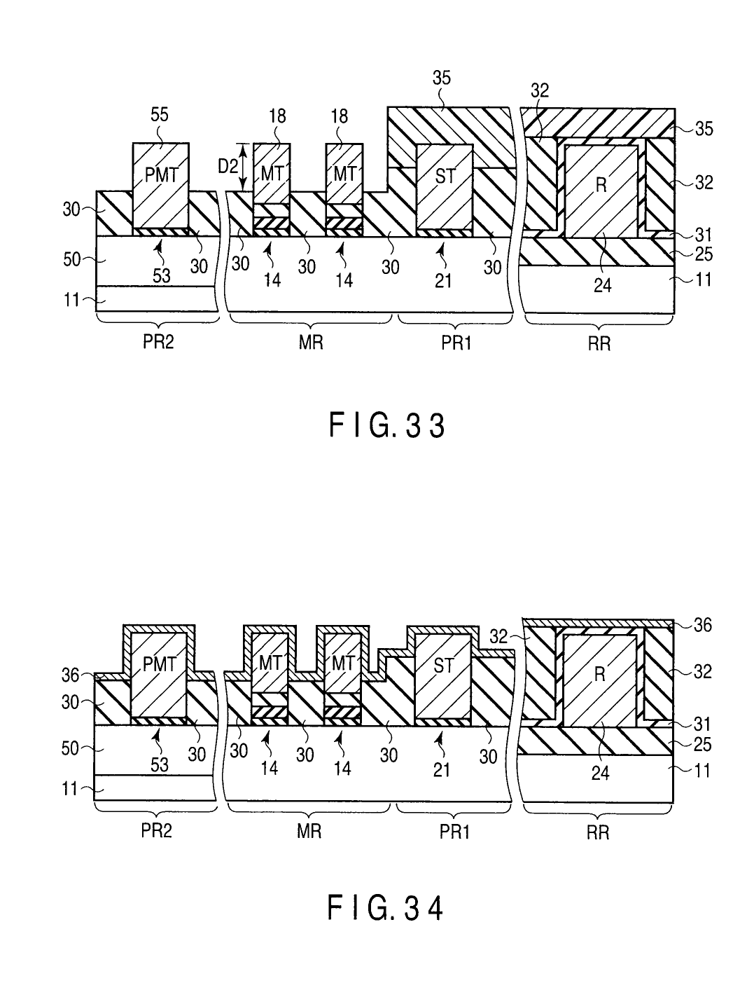

As shown in FIG. 33, a resist layer 35 is formed through lithography on the interlayer insulation layer 30 and the gate structure 21 in the peripheral transistor region 1. The interlayer insulation layer 30 is etched back to a depth D2 greater than the first depth D1, using the resist layer 35 as a mask, to expose a part of an upper portion of the control gate electrode 18 (a part of an upper portion of the stacked gate structure 14). Similarly, the interlayer insulation layer 30 in the peripheral transistor region 2 is etched back to the second depth D2, as in the case of the memory region, to expose a part of an upper portion of the gate electrode 55 (a part of an upper portion of the gate structure 53). By thus deeply etching back the interlayer insulation layer 30 in the memory region, compared to the interlayer insulation layer 30 of the peripheral transistor region 1, a difference in height is generated between the interlayer insulation layer 30 of the memory region and the interlayer insulation layer 30 of the peripheral transistor region 1. After that, the resist layer 35 is removed.

The first depth D1 is equal to or smaller than the depth from the upper surface of the gate electrode 23 to the intermediate position of the gate electrode 23, for example. The second depth D2 is larger than the depth from the upper surface of each of the control gate electrode 18 and the gate electrode 55 to the intermediate position of the control gate electrode 18, for example. The above-described first depth D1 and the second depth D2 are just examples and any depths satisfying the relationship that the second depth D2 is greater than the first depth D1 can be used (as the first depth D1 and the second depth D2).

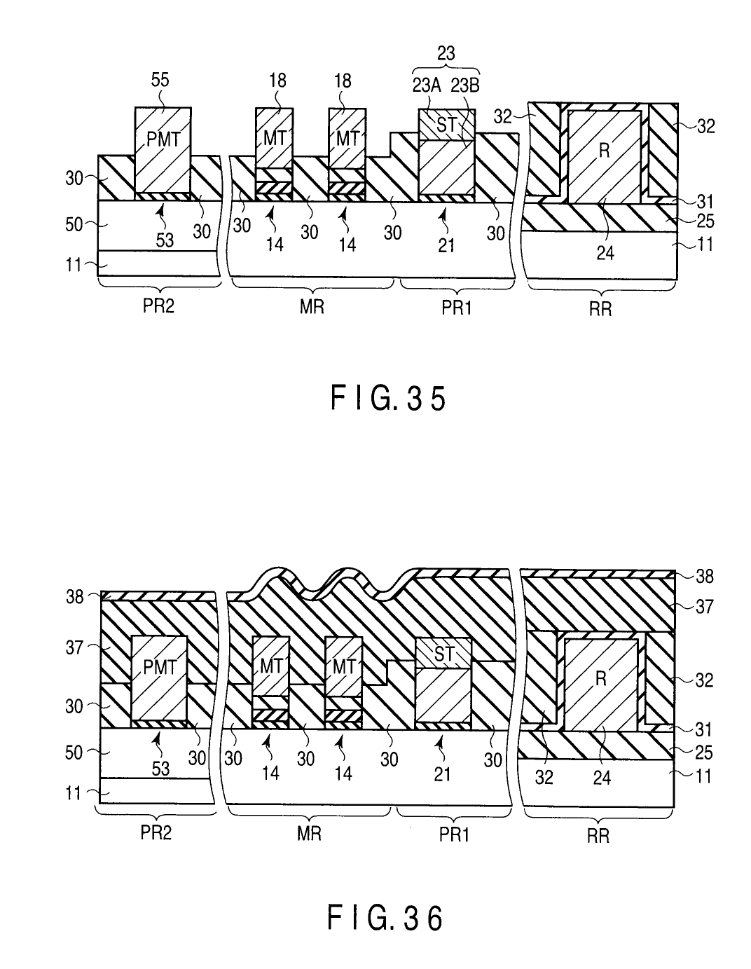

As shown in FIG. 34, a metal film 36 formed of cobalt (Co), for example, is deposited on an upper surface and side surfaces of each of the stacked gate structure 14, the gate structure 21, and the gate structure 53, through spattering, for example. Thereby, the metal film 36 adheres deeply to the stacked gate structure 14 and the gate structure 53, compared to the gate structure 21. In this state, the device is subjected to heat treatment to cause reaction between the metal film 36 and the polysilicon (the control gate electrode 18 and the gate electrodes 23 and 55). Thereby, as shown in FIG. 35, the fully silicided control gate electrode 18 and gate electrode 55 are formed. Further, the upper portion of the gate electrode 23 is silicided and the gate electrode 23 formed of a polysilicon electrode 23A and a silicide electrode 23B is formed. Not contacting the metal film 36, the resistor element 24 is not silicided. After that, the remaining metal film 36 is wet-etched.

As shown in FIG. 36, an interlayer insulation layer 37 formed of silicon oxide, for example, is deposited on the entire surface of the device through CVD. After that, a stopper film 38 to be used as a stopper in the subsequent planarization process is deposited on the interlayer insulation layer 37 through CVD. Due to a difference in height is generated in the interlayer insulation layer 30, a difference in height is generated in a boundary between the memory region and the peripheral transistor region 1 in the stopper film 38. Silicon nitride, for example, may be used as the stopper film 38. Thus, the semiconductor memory device of the present embodiment is formed.

As described above, according to the present embodiment, the resistor element 24 formed of the memory cell transistor MT having the FUSI control gate electrode 18, the selective transistor ST having the partially silicided gate electrode 23, the p-channel MOS transistor PMT having the FUSI gate electrode 55, and the resistor element 24 formed of polysilicon can be formed on the same substrate.

By performing the step of depositing the metal film 36 once and the heat treatment step once, the fully silicided control gate electrode 18 and gate electrode 55 and the partially silicided gate electrode 23 may be simultaneously formed. Thereby, the manufacturing cost can be reduced. Further, it is also possible to prevent the resistor element 24 from being silicided in this silicidation step.

The present embodiment is effective when the channel of the selective transistor ST, which is n-channel, is a surface channel, and the channel of the p-channel MOS transistor PMT is a buried channel, such as a case where the gate electrode 23 and the gate electrode 55 are doped with an n-type impurity. Then the p-channel MOS transistor PMT can be made as a surface channel by fully siliciding the gate electrode 55 of the p-channel MOS transistor PMT. As a result, variation in properties of the p-channel MOS transistor PMT can be improved.

The semiconductor memory device described in the fourth embodiment may be formed using the manufacturing method described in the second embodiment, as well as the above-described manufacturing method.

### Fifth Embodiment

In a fifth embodiment, the semiconductor memory device comprising a memory cell transistor MT having a FUSI gate electrode, a selective transistor ST having a partially silicided gate electrode, and a resistor element formed of polysilicon is manufactured, using a method different from that of the first embodiment.

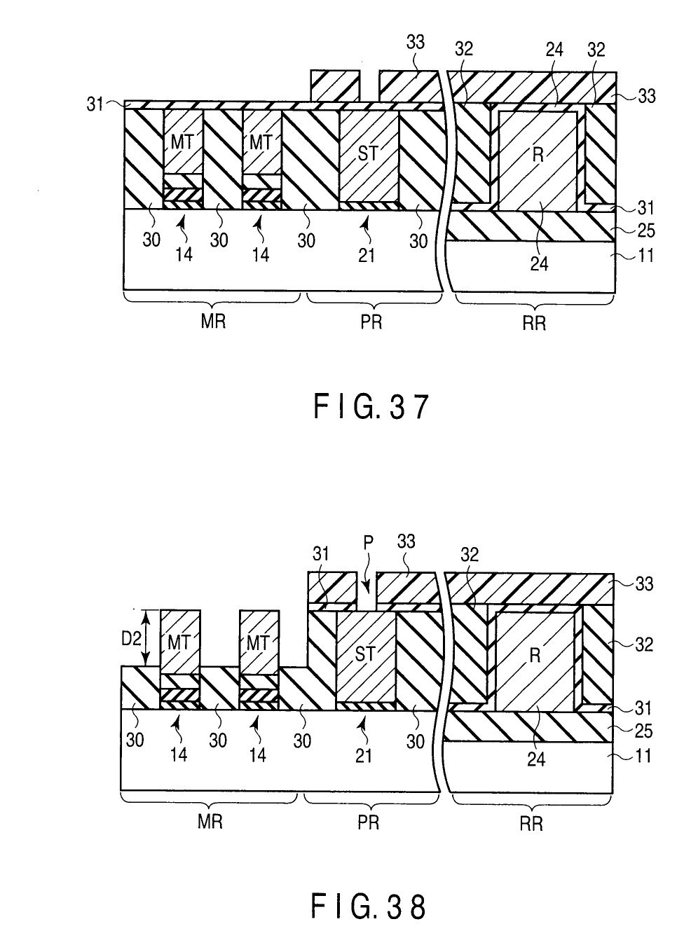

The manufacturing steps from FIG. 5 to FIG. 7 are the same as those of the first embodiment. Following those steps, as shown in FIG. 37, the resistive region and the peripheral transistor region are partially covered with the resist layer 23 through lithography. The peripheral transistor region is covered with the resist layer 33 except for the central part of the gate electrode of the selective transistor ST. The resist layer 33 needs to cover at least a part of the gate electrode of the selective transistor ST.

As shown in FIG. 38, the barrier film 31 formed in the memory region and the peripheral transistor region is removed using the resist layer 33 as a mask. Further, the interlayer insulation layer 30 of the memory region is etched back to a second depth D2. As a result, in the peripheral transistor region, the part of the interlayer insulation layer 30 which is covered with the resist layer 33 is not etched back. Further, an opening P is formed in the barrier film 31 on the gate electrode 23 of the selective transistor ST, and a part of the gate electrode 23 is exposed from the barrier film 31 via the opening P. Due to difference in etching rate between the interlayer insulation layer 30 and the polysilicon, the upper surface of the gate electrode 23 exposed by the opening P is hardly etched. After that, the resist layer 33 is removed.

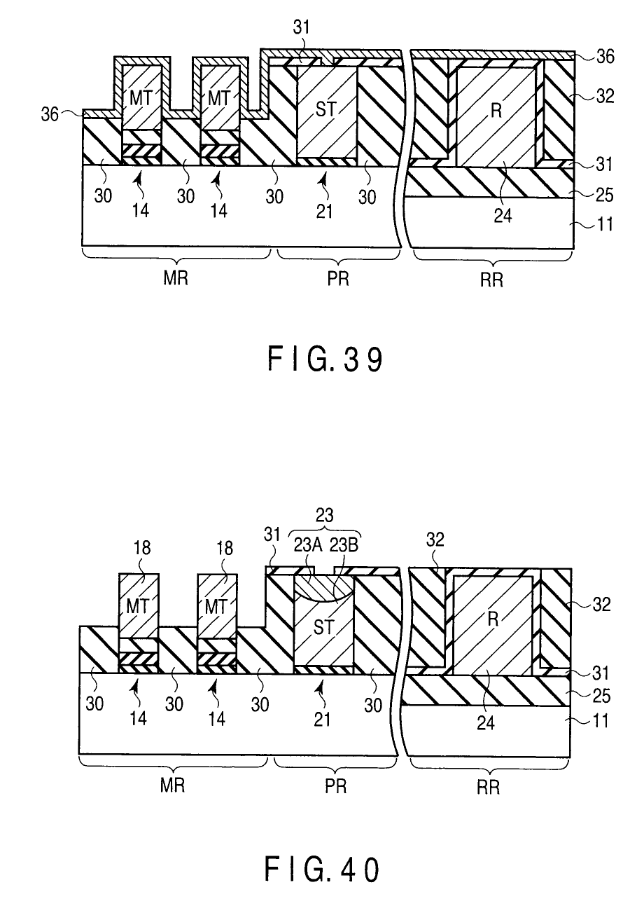

As shown in FIG. 39, a metal film 36 formed of cobalt (Co), for example, is deposited on an upper surface and side surfaces of the stacked gate structure 14 and an upper surface of the gate structure 21 through spattering, for example. Thereby, the side surfaces of the control gate electrode 18 of the stacked gate structure 14 are made into contact with the metal film 36. The metal film 36 is not formed on side surfaces of the gate electrode 23 of the stacked gate structure 21. The upper surface of the gate electrode 23 exposed by the opening P is made into contact with the metal film 36.

In this state, the device is subjected to heat treatment to cause reaction between the metal film 36 and the polysilicon (the control gate electrode 18 and the gate electrode 23). Thereby, as shown in FIG. 40, the fully silicided control gate electrode 18 is formed. Since only a part of the upper surface of the gate electrode 23 is made into contact with the metal film 36, the gate electrode 23 is partially silicided. As a result, the upper portion of the gate electrode 23 is silicided and the gate electrode 23 formed of a polysilicon electrode 23A and a silicide electrode 23B is formed.

Since the silicide electrode 23B is silicided by the metal film 36 formed in the opening P, a bottom surface of the silicide electrode 23B forms a circle with the opening P at the center. Not contacting the metal film 36, the resistor element 24 is not silicided. After that, the remaining metal film 36 is wet-etched.

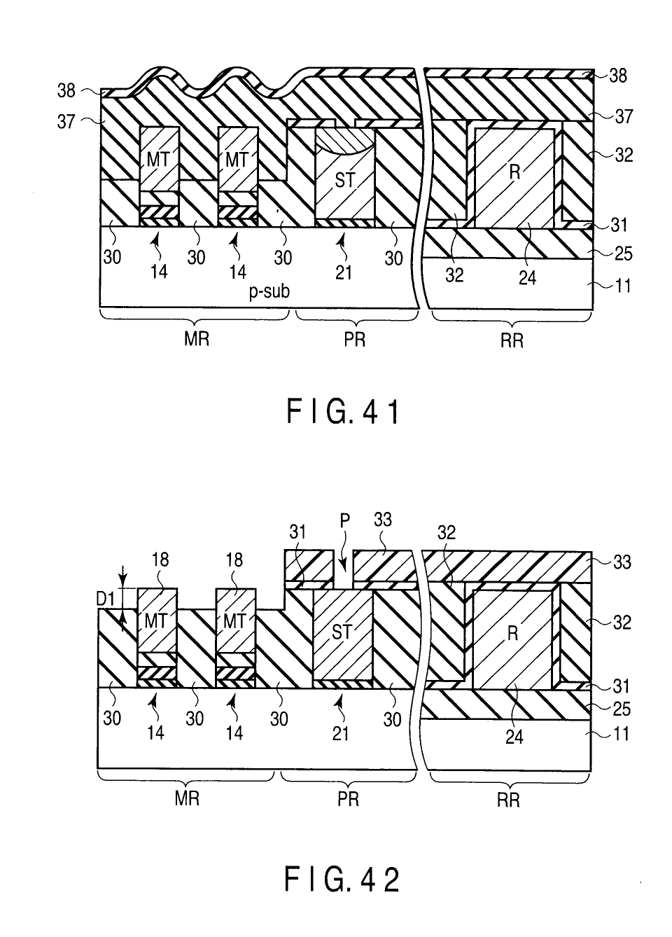

Following similar steps as those of the first embodiment, the semiconductor memory device of the present embodiment shown in FIG. 41 is formed.

The fifth embodiment needs to etch the interlayer insulation layer 30 of the memory region only once. As a result, short of etched back of the interlayer insulation layer 30 due to variation in etching process may not occur. Thereby, the control gate electrode 18 can be fully silicided in an effective manner.

### Modification of Fifth Embodiment

In a modification of the fifth embodiment, a semiconductor memory device comprising a memory cell transistor MT having a FUSI gate electrode, a selective transistor ST having a partially silicided gate electrode, and a resistor element formed of polysilicon is manufactured by a method different from that of the fifth embodiment.

The steps up to FIG. 37 are the same as those of the fifth embodiment. Following those steps, as shown in FIG. 42, the barrier film 31 formed in the memory region and the peripheral transistor region is removed using the resist layer 33 as a mask. Further, the interlayer insulation layer 30 in the memory is etched back to the first depth D1.

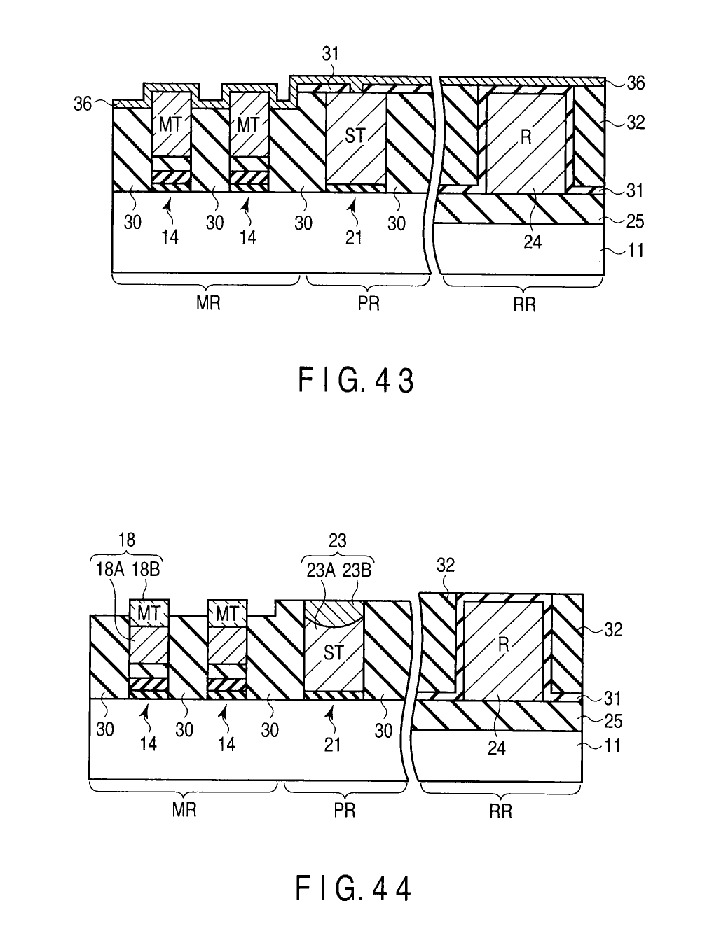

As shown in FIG. 43, a metal film 36 formed of cobalt (Co), for example, is deposited on an upper surface and side surfaces of the stacked gate structure 14 and an upper surface of the gate structure 21 through spattering, for example. Thereby, side surfaces of the control gate electrode 18 of the stacked gate structure 14 are made into contact with the metal film 36. The metal film 36 is not formed on side surfaces of the gate electrode 23 of the stacked gate structure 21. A part of the gate electrode 23 exposed by an opening P contacts the metal film 36.

In this state, the device is subjected to heat treatment to cause reaction between the metal film 36 and the polysilicon (the control gate electrode 18 and the gate electrode 23). Thereby, as shown in FIG. 44, an upper portion of the gate electrode 23 is silicided to form a polysilicon electrode 18A and a silicide electrode 18B on the polysilicon electrode 18A. Since the gate electrode 23 does not contact the metal film 36 except a part of its upper surface, only a part of the gate electrode 23 is silicided. As a result, the upper portion of the gate electrode 23 is silicided and a gate electrode 23 formed of a polysilicon electrode 23A and a silicide electrode 23B is formed.

Since the silicide electrode 23B is silicided by the metal film 36 formed in the opening P, a bottom surface of the silicide electrode 23B forms a circle with the opening P at the center. Not contacting the metal film 36, the resistor element 24 is not silicided. After that, the remaining metal film 36 is wet-etched and the barrier film 31 in the peripheral transistor region is removed.

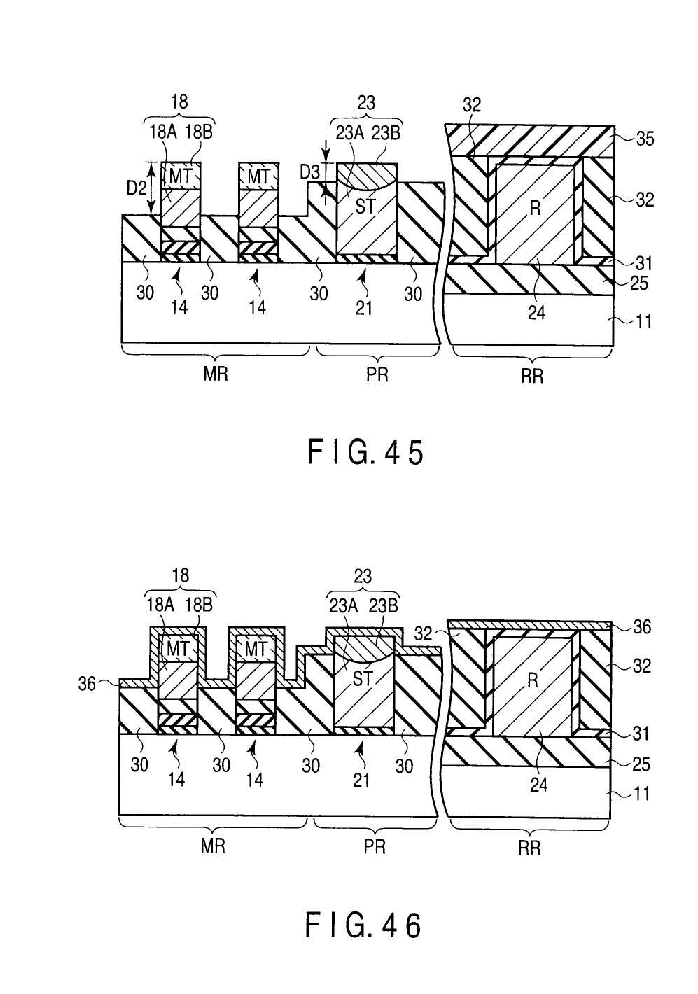

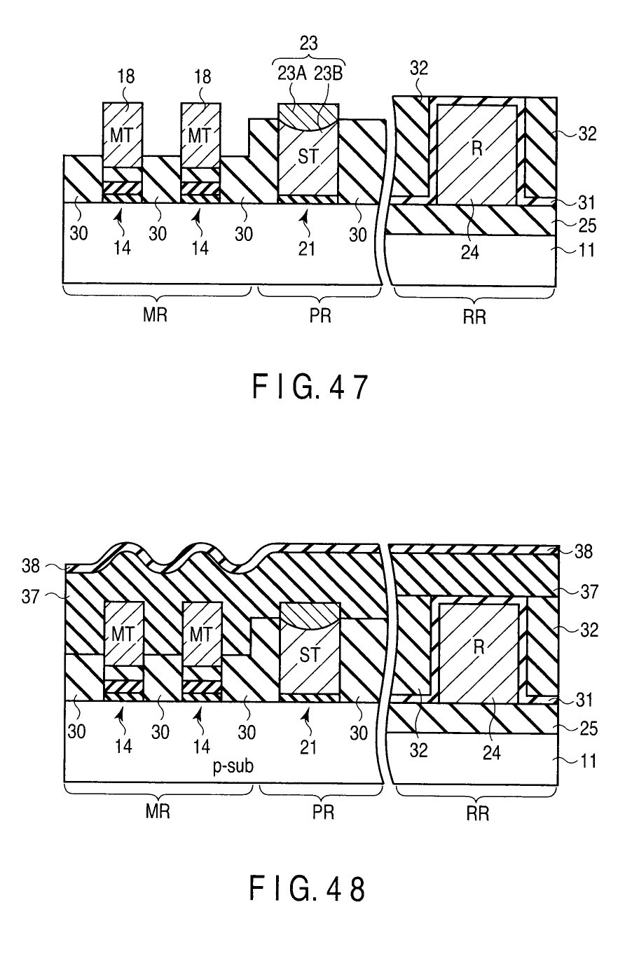

As shown in FIG. 45, a resist layer 35 is formed in the resistive region through lithography. The interlayer insulation layer 30 is etched back by a third depth D3. As a result, in the memory region, the control gate electrode 18 is exposed to a depth D2 greater than the depth D3 from its upper surface. In the peripheral transistor region, the gate electrode 23 is exposed to the third depth D3 from its upper surface.

By thus deeply etching back the interlayer insulation layer 30 of the memory region, compared to the interlayer insulation layer 30 of the peripheral transistor region, a difference in height is generated between the interlayer insulation layer 30 in the memory region and the interlayer insulation layer 30 in the peripheral transistor region. After that, the resist layer 35 is removed.

The third depth D3 is equal to or smaller than the depth from the upper surface of the gate electrode 23 to the intermediate position of the gate electrode 23, for example. The second depth D2 is larger than the depth from the upper surface of control gate electrode 18 to the intermediate position of the control gate electrode 18, for example. It is to be noted, however, that the above-described third depth D3 and the second depth D2 are just examples. The second depth D2 equals to the depth obtained by adding the first depth D1 and the third depth D3.

As shown in FIG. 46, a metal film 36 formed of cobalt (Co), for example, is deposited on an upper surface and side surfaces of each of the stacked gate structure 14 and the gate structure 21 through spattering, for example. Thereby, the metal film 36 more deeply adheres to the side surfaces of the stacked gate structure 14 than the side surfaces of the gate structure 21. In this state, the device is subjected to heat treatment to cause reaction between the metal film 36 and the polysilicon (the control gate electrode 18 and the gate electrode 23). Thereby, as shown in FIG. 48, the fully silicided control gate electrode 18 is formed.

Since the side surfaces of the gate electrode 23 do not contact the metal film 36 except the upper portion, the gate electrode 23 is partially silicided. As a result, the upper portion of the gate electrode 23 is silicided and the gate electrode 23 formed of a polysilicon electrode 23A and a silicide electrode 23B is formed. When the third depth D3 is small, a lower surface of the silicide electrode 23B may be formed in a circular shape. Not contacting the metal film 36, the resistor element 24 is not silicided. After that, the remaining metal film 36 is wet-etched.

Following steps similar to those of the first embodiment, the semiconductor memory device of the present modification shown in FIG. 48 is fabricated.

This modification enables the silicide gate electrode 23B of the stacked gate electrode 21 of the selective transistor ST to increase in size, compared to the fifth embodiment. As a result, the resistance of the stacked gate electrode 21 can be decreased.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate;
a memory cell provided on the semiconductor substrate and having a stacked gate structure formed by sequentially stacking a tunnel insulation film, a charge storage layer, a block insulation film, and a control gate electrode;
a first transistor having a first gate electrode provided on the semiconductor substrate via a gate insulation film; and
a resistor element provided on the semiconductor substrate and formed of polysilicon,
wherein the control gate electrode is entirely formed of a silicide layer, and
an upper portion of the first gate electrode partially includes a silicide layer.

2. The device according to claim 1, further comprising:
an interlayer insulation layer provided on the memory cell, the first transistor and the resistor element; and
a stopper film provided on the interlayer insulation layer,
wherein the stopper film has a difference in height between the memory cell and the first transistor.

3. The device according to claim 1, further comprising a barrier film covering the resistor element.

4. The device according to claim 1, further comprising an insulation film provided between the semiconductor substrate and the resistor element.

5. The device according to claim 1, further comprising a second transistor including a second gate electrode provided on the semiconductor substrate via a gate insulation film,
wherein the second gate electrode is entirely formed of a silicide layer.

6. The device according to claim 5, wherein
the first transistor is an n-channel MOS transistor, and
the second transistor is a p-channel MOS transistor.

7. The device according to claim 6, wherein the second transistor is a buried-channel MOS transistor.

8. A manufacturing method of a semiconductor memory device, the method comprising:
forming a memory cell having a stacked gate structure formed by sequentially stacking a tunnel insulation film, a charge storage layer, a block insulation film, and a control gate electrode formed of polysilicon on a first region of a semiconductor substrate;
forming a transistor having a gate electrode provided on a second region of the semiconductor substrate via a gate insulation film, the gate electrode being formed of polysilicon;
forming a resistor element formed of polysilicon on a third region of the semiconductor substrate;
depositing an insulation layer on the first region and the second region of the semiconductor substrate to fill in spaces between elements;
forming a barrier film on an upper surface and side surfaces of the resistor element;
etching back an insulation layer of the second region to a first depth to expose a part of the gate electrode;
etching back an insulation layer of the first region to a second depth greater than the first depth to expose a part of the control gate electrode;
forming a metal film on the exposed parts of the control gate electrode and the gate electrode; and
performing heat treatment to cause reaction between the metal film and the polysilicon.

9. The method according to claim 8, wherein
the control gate electrode is entirely formed of a silicide layer,
an upper portion of the gate electrode partially includes a silicide layer, and
the resistor element is formed of polysilicon.

10. The method according to claim 8, wherein
the first depth is equal to or smaller than a depth from an upper surface to an intermediate position of the gate electrode, and
the second depth is larger than a depth from an upper surface to an intermediate position of the control gate electrode.

11. The method according to claim 8, wherein
the metal film is further formed on the barrier film, and
the barrier film prevents reaction between the polysilicon of the resistor element and the metal film from being caused by the heat treatment.

12. The method according to claim 8, further comprising depositing an insulation layer on the third region of the semiconductor substrate after forming the barrier film.

13. A manufacturing method of a semiconductor memory device, the method comprising:
forming a memory cell having a stacked gate structure formed by sequentially stacking a tunnel insulation film, a charge storage layer, a block insulation film, and a control gate electrode formed of polysilicon on a first region of a semiconductor substrate;
forming a transistor having a gate electrode provided on a second region of the semiconductor substrate via a gate insulation film, the gate electrode being formed of polysilicon;
forming a resistor element formed of polysilicon on a third region of the semiconductor substrate;
depositing an insulation layer on the first region and the second region of the semiconductor substrate to fill in spaces between elements;
forming a barrier film on an upper surface and side surfaces of the resistor element;
etching back the insulation layer to a first depth to expose an upper portion of the control gate electrode and an upper portion of the gate electrode;
forming a first metal film in the exposed portions of the control gate electrode and the gate electrode;
performing a first heat treatment to cause reaction between the first metal film and the polysilicon;
forming a resist to cover the exposed portion of the gate electrode;
forming a second metal film on the exposed portion of the control gate electrode; and
performing a second heat treatment to cause reaction between the second metal film and the polysilicon.

14. The method according to claim 13, wherein
the control gate electrode is entirely formed of a silicide layer,
an upper portion of the gate electrode partially includes a silicide layer, and
the resistor element is formed of polysilicon.

15. The method according to claim 13, wherein the first depth is smaller than a depth from an upper surface to an intermediate position of the gate electrode or the control gate electrode.

16. The method according to claim 13, wherein
the first metal film is further formed on the barrier film, and
the barrier film prevents reaction between the polysilicon of the resistor element and the first metal film by the first heat treatment.

17. The method according to claim 13, wherein
the second metal film is further formed on the barrier film, and
the barrier film prevents reaction between the polysilicon of the resistor element and the second metal film by the second heat treatment.

18. The method according to claim 13, further comprising depositing an insulation layer on the third region of the semiconductor substrate after forming the barrier film.
